(19) United States
(12) Patent Application Publication
(10) Pub. No.: US 2025/0210489 A1
(43) Pub. Date: Jun. 26, 2025

(54) PACKAGING DEVICE AND MANUFACTURING METHOD THEREOF

(71) Applicant: Innolux Corporation, Miaoli County (TW)

(72) Inventors: Ker-Yih Kao, Miaoli County (TW); Jeng-Nan Lin, Miaoli County (TW); Yen-Fu Liu, Miaoli County (TW); Ju-Li Wang, Miaoli County (TW)

(73) Assignee: Innolux Corporation, Miaoli County (TW)

(21) Appl. No.: 18/963,544

(22) Filed: Nov. 28, 2024

Related U.S. Application Data
(60) Provisional application No. 63/614,661, filed on Dec. 25, 2023.

(30) Foreign Application Priority Data
Aug. 9, 2024 (CN) 202411093673.6

(51) Int. Cl. H01L 23/498; H01L 21/48; H01L 23/00; H01L 23/31; H01L 23/373

(52) U.S. Cl. CPC H01L 23/49827; H01L 21/486; H01L 23/3107; H01L 24/20; H01L 23/3735; H01L 24/19; H01L 2224/19; H01L 2224/2105; H01L 2224/211; H01L 2224/221

(57) ABSTRACT

A packaging device and a manufacturing method thereof are provided. The packaging device includes an electronic unit, a conductive block, and a packaging layer. The conductive block is electrically connected to the electronic unit and has a first side surface. The packaging layer surrounds the electronic unit and the conductive block. A roughness of the first side surface is greater than a roughness of a second side surface of the packaging layer. The manufacturing method of the package device includes: providing a carrier; disposing the conductive block on the carrier, wherein the conductive block has the first side surface; disposing the electronic unit on the carrier; forming the packaging layer on the carrier, so that the packaging layer surrounds the electronic unit and the conductive block; and removing the carrier.

### CROSS-REFERENCE TO RELATED APPLICATION

This application claims the priority benefit of U.S. provisional application Ser. No. 63/614,661, filed on Dec. 25, 2023, and China application serial no. 202411093673.6, filed on Aug. 9, 2024. The entirety of each of the above-mentioned patent applications is hereby incorporated by reference herein and made a part of this specification.

### BACKGROUND

### Technical Field

The disclosure relates to a packaging device and a manufacturing method thereof, and more particularly to a packaging device and a manufacturing method thereof capable of improving yield.

### Description of Related Art

The electronic device or the splicing electronic device are widely applied to different fields such as communication, display, automobile, or aviation. With the rapid development of the electronic device, the electronic device is being developed toward being lighter and thinner, so the reliability or quality requirements of the electronic device are higher.

### SUMMARY

The disclosure provides a packaging device and a manufacturing method thereof, which can improve yield.

According to an embodiment of the disclosure, a packaging device includes an electronic unit, a conductive block, and a packaging layer. The conductive block is electrically connected to the electronic unit and has a first side surface. The packaging layer surrounds the electronic unit and the conductive block. A roughness of the first side surface is greater than a roughness of the second side surface of the packaging layer.

According to an embodiment of the disclosure, a manufacturing method of a packaging device includes the following steps. A carrier is provided. A conductive block is disposed on the carrier. The conductive block has a first side surface. An electronic unit is disposed on the carrier. A packaging layer is formed on the carrier, so that the packaging layer surrounds the electronic unit and the conductive block. The carrier is removed.

### BRIEF DESCRIPTION OF THE DRAWINGS

The drawings are included to provide a further understanding of the disclosure, and the drawings are incorporated into the specification and constitute a part of the specification. The drawings illustrate embodiments of the disclosure and serve to explain principles of the disclosure together with the description.

FIG. 1A to FIG. 1G are cross-sectional schematic views of a manufacturing method of a packaging device according to a first embodiment of the disclosure.

FIG. 1H is a top schematic view of a conductive block of FIG. 1A.

FIG. 2A is a cross-sectional schematic view of a conductive block of a packaging device according to a second embodiment of the disclosure.

FIG. 2B is a top schematic view of a conductive block of FIG. 2A.

FIG. 3 is a cross-sectional schematic view of a packaging device according to a third embodiment of the disclosure.

FIG. 4 is a cross-sectional schematic view of a packaging device according to a fourth embodiment of the disclosure.

FIG. 5A to FIG. 5C are cross-sectional schematic views of a manufacturing method of a packaging device according to a fifth embodiment of the disclosure.

FIG. 6 is a cross-sectional schematic view of a packaging device according to a sixth embodiment of the disclosure.

FIG. 7 is a cross-sectional schematic view of a packaging device according to a seventh embodiment of the disclosure.

FIG. 8A to FIG. 8C are cross-sectional views of a manufacturing method of a packaging device according to an eighth embodiment of the disclosure.

### DESCRIPTION OF THE EMBODIMENTS

The disclosure can be understood by referring to the following detailed description in conjunction with the drawings. It should be noted that in order to facilitate the understanding of the reader and the brevity of the drawings, multiple drawings in the disclosure only depict a part of an electronic device, and specific elements in the drawings are not drawn according to actual scale. In addition, the number and the size of each element in the drawings are for illustration only and are not intended to limit the scope of the disclosure.

In the following specification and claims, terms such as “containing” and “including” are open-ended terms, so the terms should be interpreted as “containing but not limited to . . . ”.

It should be understood that when an element or a film layer is referred to as being “on” or “connected to” another element or film layer, the element or the film layer may be directly on the other element or film layer or directly connected to the other element or film layer, or there may be an element or a film layer inserted between the two (indirect case). In contrast, when an element is referred to as being “directly on” or “directly connected to” another element or film layer, there is no element or film layer inserted between the two.

Although the terms first, second, third . . . may be used to describe various constituent elements, the constituent elements are not limited by the terms. The terms are only used to distinguish a single constituent element from other constituent elements in the specification. The same terms may not be used in the claims, but replaced by first, second, third . . . according to the order in which the elements are declared in the claims. Therefore, in the following specification, a first constituent element may be a second constituent element in the claims.

As used herein, the terms “about”, “approximately”, “substantially”, and “roughly” generally indicate within 10%, within 5%, within 3%, within 2%, within 1%, or within 0.5% of a given value or range. The number given here is an approximate number, that is, in the case where “about”, “approximately”, “substantially”, or “roughly” is not specifically stated, the meaning of “about”, “approximately”, “substantially”, or “roughly” may still be implied.

In some embodiments of the disclosure, terms related to bonding and connection, such as “connection” and “interconnection”, unless otherwise defined, may refer to that two structures are directly in contact or may also refer to that two structures are not directly in contact, wherein there is another structure disposed between the two structures. Also, the terms related to bonding and connection may further include the case where the two structures are both movable or the two structures are both fixed. Furthermore, the term “coupling” includes any direct or indirect electrical connection means.

In some embodiments of the disclosure, an optical microscope (OM), a scanning electron microscope (SEM), an α-step film thickness profiler, an ellipsometer, or other suitable manners may be used to measure the area, width, thickness, or height of each element or the distance or spacing between the elements. In detail, according to some embodiments, a scanning electron microscope may be used to obtain a cross-sectional structural image including an element to be measured and measure the area, width, thickness, or height of each element or the distance or spacing between the elements.

In some embodiments of the disclosure, directional terms such as “upper”, “lower”, “front”, “back”, “left”, and “right” mentioned herein are only used for reference to the directions of the drawings. Therefore, the directional terms are used to illustrate, but not to limit, the disclosure.

In the disclosure, roughness judgment may be defined with SEM observation. On a concave-convex surface, it can be seen that there is a distance difference of 0.15 micrometers (μm) to 1 μm between peaks and valleys of surface undulations. The measurement of the roughness judgment may include observing the condition of the surface undulations at the same appropriate magnification using the SEM, a transmission electron microscope (TEM), etc., and comparing the undulation conditions through taking samples per unit length (for example, 10 μm), which is the roughness range. Here, “appropriate magnification” means that at least one surface has a roughness (Rz) or an average roughness (Ra) of at least 10 undulating peaks that can be seen under the field of view of such a magnification.

As used herein, the terms “film” and/or “layer” may refer to any continuous or discontinuous structure and material (such as a material deposited by a method disclosed herein). For example, the film and/or the layer may include a two-dimensional material, a three-dimensional material, nanoparticles, or even a partial or complete molecular layer, a partial or complete atomic layer, or atom and/or molecule clusters. The film or the layer may include a material or a layer having pinholes, which may be at least partially continuous.

A packaging device of the disclosure may be applied to an electronic device, and the electronic device may include a display device, an antenna device, a sensing device, or a splicing device, but the disclosure is not limited thereto. The electronic device may be a bendable or flexible electronic device. The electronic device may, for example, include a liquid crystal light emitting diode (LED). The light emitting diode may include, for example, an organic LED (OLED), a mini LED, a micro LED, a quantum dot (QD) LED (which may be, for example, QLED or QDLED), fluorescence, phosphor, or other suitable materials, and the materials may be arbitrarily arranged and combined, but the disclosure is not limited thereto. The antenna device may be, for example, a liquid crystal antenna, but the disclosure is not limited thereto. The splicing device may be, for example, a display splicing device or an antenna splicing device, but the disclosure is not limited thereto. The electronic device may include an electronic unit. The electronic unit may include a passive element, an active element, or a combination of the above, such as a capacitor, a resistor, an inductor, a varactor diode, a variable capacitor, a filter, a diode, a transistor, a transducer, a microelectromechanical system (MEMS), a chip (for example, a known good die (KGD)), an antenna unit, a semiconductor-related process structure, or a semiconductor-related process structure disposed on a substrate (for example, polyimide, glass, a silicon substrate, or other suitable substrate materials), but the disclosure is not limited thereto. It should be noted that the electronic device of the disclosure may be various combinations of the above devices, but the disclosure is not limited thereto. A manufacturing method of the electronic device of the disclosure may be applied to, for example, a wafer-level package (WLP) process or a panel-level package (PLP) process, wherein the wafer-level package or the panel-level package process may include a chip-first process or a chip-last process, but the disclosure is not limited thereto. The electronic device of the disclosure may be applied to, for example, a power module or a semiconductor packaging device, but the disclosure is not limited thereto. The electronic device may include a system on a chip (SoC), a system in a package (SiP), an antenna in a package (AiP), or various combinations of the above devices, but the disclosure is not limited thereto. It should be noted that the electronic device may be any arrangement or combination of the aforementioned, but the disclosure is not limited thereto. The disclosure will be described below using the packaging device, but the disclosure is not limited thereto.

It should be noted that in the following embodiments, the features in several different embodiments may be replaced, reorganized, and mixed to complete other embodiments without departing from the spirit of the disclosure. The features of the various embodiments may be arbitrarily mixed and matched for use as long as the features do not violate the spirit of the invention or conflict with each other.

Reference will now be made in detail to the exemplary embodiments of the disclosure, and examples of the exemplary embodiments are illustrated in the drawings. Wherever possible, the same reference numerals are used in the drawings and the description to indicate the same or similar parts.

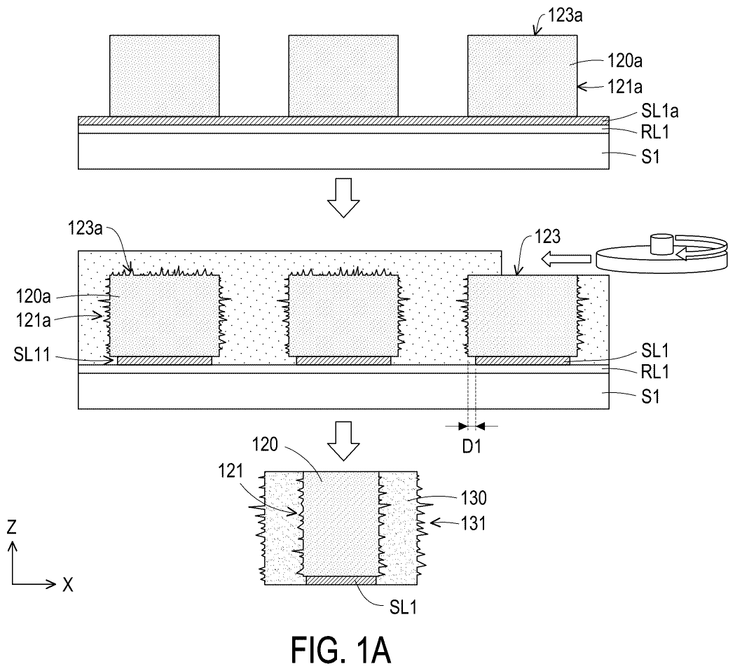

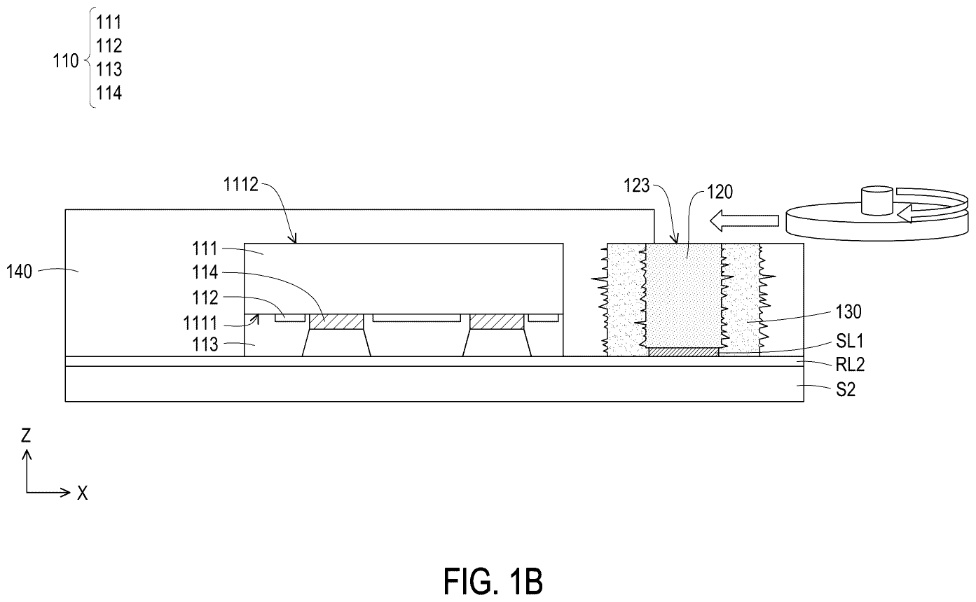

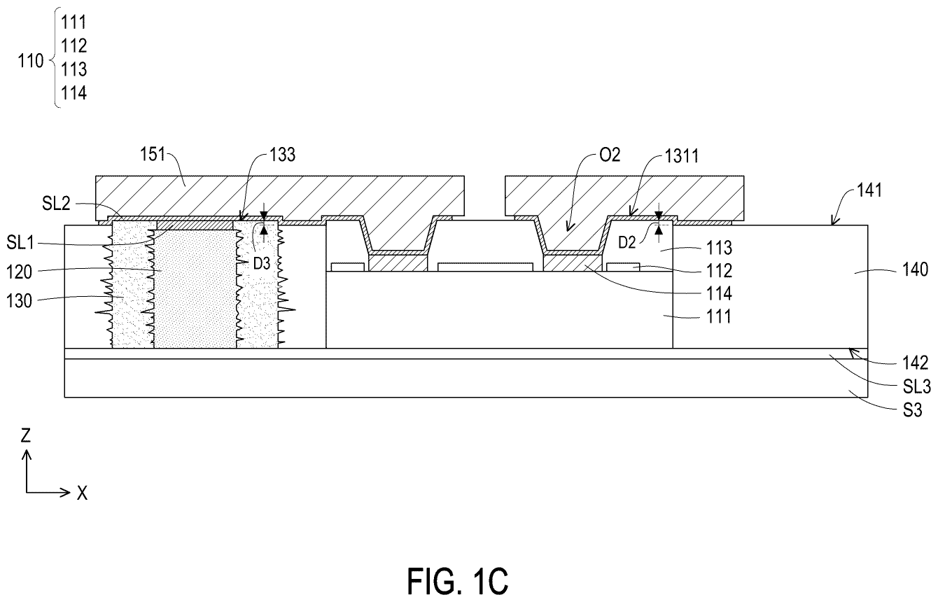

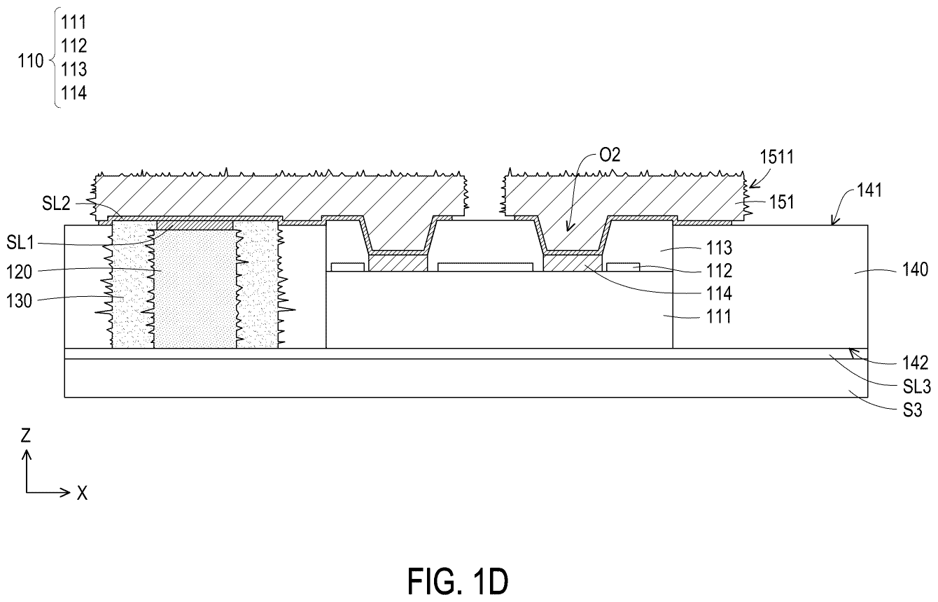

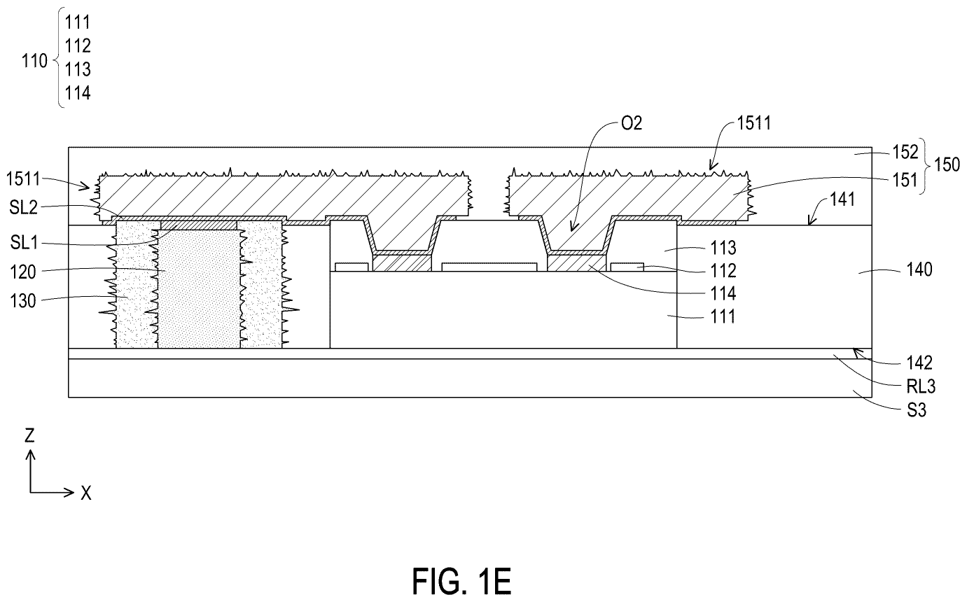

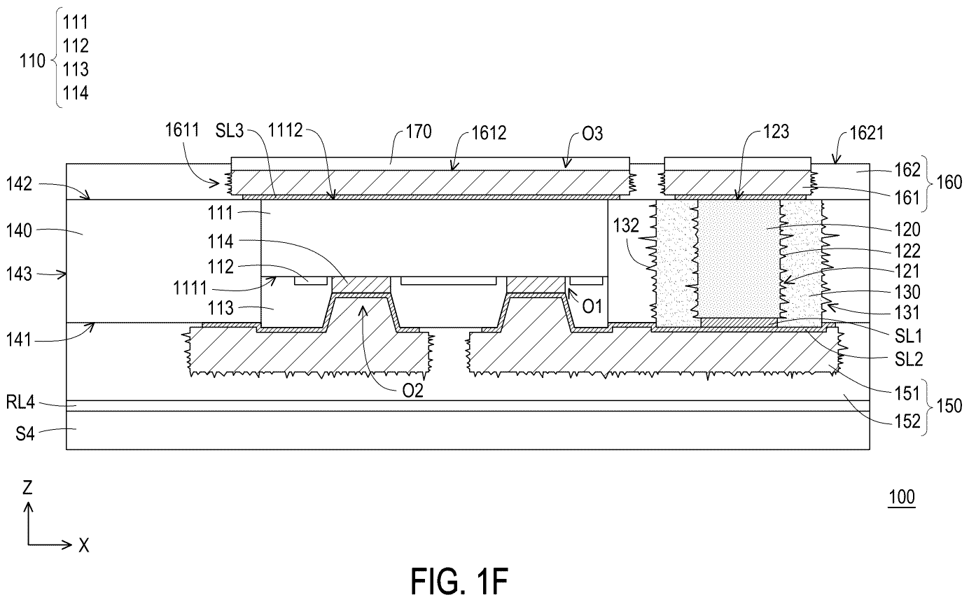

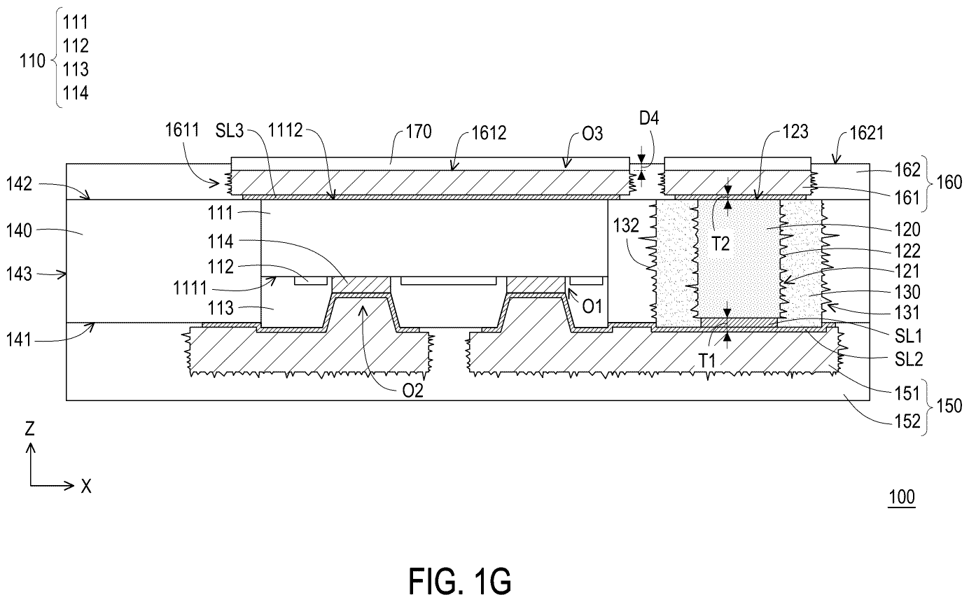

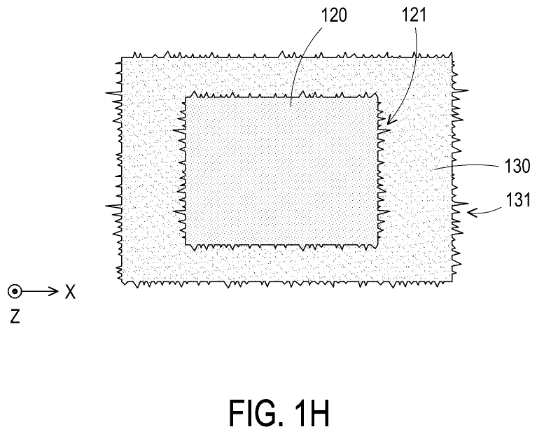

FIG. 1A to FIG. 1G are cross-sectional schematic views of a manufacturing method of a packaging device according to a first embodiment of the disclosure. FIG. 1H is a top schematic view of a conductive block of FIG. 1A.

Please refer to FIG. 1G. A packaging device 100 of the embodiment includes an electronic unit 110, a conductive block 120, a first seed layer SL1, an insulation layer 130, a packaging layer 140, a second seed layer SL2, a first circuit structure 150, a third seed layer SL3, a second circuit structure 160, and a conductive member 170.

Specifically, the electronic unit 110 includes a chip 111, a first insulation layer 112, a second insulation layer 113, and a pad 114. The chip 111 has an active surface 1111 and a back surface 1112 opposite to each other. The first insulation layer 112 is disposed under the active surface 1111 of the chip 111, and the first insulation layer 112 has an opening O1 that may expose the chip 111. The pad 114 is disposed in the opening O1, and the pad 114 is electrically connected to the active surface 1111 of the chip 111. Along a normal direction (a direction Z) of the packaging device 100, the first insulation layer 112 is disposed between the chip 111 and the second insulation layer 113. According to some embodiments, at least part of the second insulation layer 113 may be disposed in the opening O1, but the disclosure is not limited thereto. The second insulation layer 113 has an opening O2 that may expose the chip 111. The opening O2 may overlap with the opening O1 in the direction Z. The first insulation layer 112 referred to in the disclosure may include an organic material or an inorganic material. The organic material may include polyimide (PI), poly-p-xylylene (also referred to as parylene), benzocyclobutene (BCB), epoxy, polycarbonate (PC), polyethylene terephthalate (PET), polyethylene naphthalate (PEN), polymer, or other suitable organic materials, but the disclosure is not limited thereto. The inorganic material includes silicon oxide, silicon nitride, silicon oxynitride, or other suitable inorganic materials, but the disclosure is not limited thereto. In the disclosure, the thickness of the first insulation layer 112 may be less than the thickness of the second insulation layer 113, wherein the Young's modulus of the first insulation layer 112 may be greater than the Young's modulus of the second insulation layer 113. For example, the Young's modulus of the second insulation layer 113 may be between 3 GPa and 25 GPa. Through the above configuration, the risk of chip breakage of the electronic unit 110 during a cutting process may be reduced, but the disclosure is not limited thereto. According to some embodiments, the packaging device 100 may include at least one electronic unit 110.

The conductive block 120 is disposed adjacent to the electronic unit 110, and the conductive block 120 may be electrically connected to the electronic unit 110. According to some embodiments, the conductive block 120 and the electronic unit 110 may be disposed, for example, along a direction (a direction X) perpendicular to the normal direction (the direction Z) of the packaging device 100. The conductive block 120 has a first side surface 121. According to some embodiments, the packaging device 100 may include one conductive block 120, two conductive blocks 120, or even more than two conductive blocks 120, but the disclosure is not limited thereto. The impedance of the conductive block 120 may be greater than or equal to 1*10⁻⁶ (ohm-cm) and less than or equal to 1*10⁻³ (ohm-cm). The material of the conductive block 120 may include metal, a semiconductor structure, or other suitable conductive materials.

The first seed layer SL1 is disposed on the conductive block 120. According to some embodiments, the first seed layer SL1 may overlap with the conductive block 120 or the first seed layer SL1 may contact the conductive block 120. According to some embodiments, along the direction X, the width of the first seed layer SL1 is less than or equal to the width of the conductive block 120. The width referred to in the disclosure may be, for example, the maximum width in the cross-sectional schematic view. The first seed layer SL1 may include titanium, copper, tantalum, tungsten, nickel, ruthenium, rubidium, gallium, or other suitable materials. According to some embodiments, the conductive block 120 may be deposited or adhesion may be improved through the seed layer, but the disclosure is not limited thereto.

The insulation layer 130 surrounds and contacts the first side surface 121 of the conductive block 120 and the first seed layer SL1. Furthermore, a part 122 of the conductive block 120 extends outward from the first side surface 121 into the insulation layer 130. Through the above design, the bonding force between different film layers may be improved, but the disclosure is not limited thereto. According to some embodiments, along the direction Z, at least part of the insulation layer 130 overlaps with the conductive block 120. In other words, since the width of the first seed layer SL1 is less than the width of the conductive block 120, along the direction Z, at least part of the insulation layer 130 overlaps with the conductive block 120, so as to improve the bonding force between different film layers, but the disclosure is not limited thereto. The insulation layer 130 has a third side surface 131.

The packaging layer 140 surrounds the electronic unit 110, the conductive block 120, and the insulation layer 130. Furthermore, the insulation layer 130 is disposed between the conductive block 120 and the packaging layer 140, and a part 132 of the insulation layer 130 extends outward from the third side surface 131 into the packaging layer 140. In other words, along the direction Z, at least part of the insulation layer 130 overlaps with the packaging layer 140. Through the above design, the bonding force between different film layers may be improved, but the disclosure is not limited thereto. The packaging layer 140 has a first surface 141, a second surface 142, and a second side surface 143. The first surface 141 and the second surface 142 are opposite to each other, and the second side surface 143 connects the first surface 141 and the second surface 142. The surrounding referred to in the disclosure means that in the cross-sectional schematic view, an element A at least contacts two side surfaces of an element B or the element B is disposed between two adjacent parts of the element A. The insulation layer 130 and the packaging layer 140 may include the same material or different materials.

The first circuit structure 150 is disposed on the first surface 141 of the packaging layer 140. The electronic unit 110 may be electrically connected to the conductive block 120 through the first circuit structure 150. The first circuit structure 150 may include at least one second seed layer SL2, at least one conductive layer 151, and at least one dielectric layer 152. The first seed layer SL1 is disposed between the conductive block 120 and the second seed layer SL2. According to some embodiments, the second seed layer SL2 may be disposed on a surface of the insulation layer 130, on the first surface 141 of the packaging layer 140, and in the opening O2 of the second insulation layer 113. The second seed layer SL2 may contact the first seed layer SL1 and the pad 114. The conductive layer 151 is disposed on a surface of the second seed layer SL2 facing away from the packaging layer 140 and in the opening O2 of the second insulation layer 113. The dielectric layer 152 is disposed on a surface of the conductive layer 151 facing away from the packaging layer 140, and the dielectric layer 152 may cover a part of the packaging layer 140. According to some embodiments, at least part of the second seed layer SL2 is disposed between the packaging layer 140 and the conductive layer 151 and at least part of the dielectric layer 152 is disposed between the packaging layer 140 and the conductive layer 151. Through the above design, the reliability of the packaging device may be improved, but the disclosure is not limited thereto.

The second circuit structure 160 is disposed on the second surface 142 of the packaging layer 140. The second circuit structure 160 is disposed opposite to the first circuit structure 150. The second circuit structure 160 may include at least one third seed layer SL3, at least one conductive layer 161, and at least one dielectric layer 162. The conductive block 120 is disposed between the third seed layer SL3 and the second seed layer SL2. According to some embodiments, the third seed layer SL3 is disposed on another surface of the insulation layer 130, the second surface 142 of the packaging layer 140, and the back surface 1112 of the chip 111. The third seed layer SL3 may contact the conductive block 120. The conductive layer 161 is disposed on a surface of the third seed layer SL3 facing away from the packaging layer 140. The dielectric layer 162 is disposed on a surface of the conductive layer 161 facing away from the packaging layer 140, and the dielectric layer 162 may cover a part of the packaging layer 140. The dielectric layer 162 has an opening O3 that may expose the conductive layer 161.

In the embodiment, the conductive layer 151 of the first circuit structure 150 may be electrically connected to the conductive block 120 through the second seed layer SL2 and the first seed layer SL1, and the conductive layer 161 of the second circuit structure 160 may be electrically connected to the conductive block 120 through the third seed layer SL3, so that the first circuit structure 150 may be electrically connected to the second circuit structure 160 through the conductive block 120. In addition, in the embodiment, the conductive layer 151 of the first circuit structure 150 may also be electrically connected to the pad 114 of the electronic unit 110 through the second seed layer SL2, so that the electronic unit 110 may be electrically connected to the second circuit structure 160 through the first circuit structure 150 and the conductive block 120.

According to some embodiments, the first circuit structure 150 and the second circuit structure 160 may also be referred to as redistribution layers (RDL). The redistribution structure may be electrically connected to a chip or other electronic units through a solder ball or other bonding elements. The redistribution structure may include at least one dielectric layer and at least one conductive layer alternately stacked along the direction Z. Through the at least one dielectric layer and the at least one conductive layer, circuits may be re-routed and/or the circuit fan-out or fan-in area may be increased, or different electronic units may be electrically connected to each other through the redistribution structure. For example, a pitch between two adjacent contact pads at an end of the redistribution structure contacting the electronic unit may be less than or equal to a pitch between two adjacent contact pads at an end of the redistribution structure away from the electronic unit. Therefore, the redistribution structure may adjust the circuit fan-out condition or electrically connect a circuit structure/an electronic element with a first pitch to a circuit structure/an electronic unit with a second pitch, but the disclosure is not limited thereto. A method of forming the redistribution structure may include forming the at least one dielectric layer and the at least one conductive layer by using a lithography process, a surface treatment process, a laser process, an electroplating process, a deposition process, or other processes. The surface treatment process includes roughening or activating a dielectric layer surface or a conductive layer surface to improve the bonding ability thereof. For example, the bonding force with the subsequent film layer is improved through increasing the surface roughness. The redistribution structure may include multiple dielectric layers, wherein the materials of the dielectric layers may be the same or different. The material of the dielectric layer may include an organic material or an inorganic material. The organic material may include polyimide, poly-p-xylylene, benzocyclobutene, epoxy, polycarbonate, polyethylene terephthalate, polyethylene naphthalate, polymer, or other suitable organic materials, but the disclosure is not limited thereto. The inorganic material includes glass, silicon oxide, silicon nitride, silicon oxynitride, or other suitable inorganic materials, but the disclosure is not limited thereto.

In the embodiment, the roughness of the first side surface 121 of the conductive block 120 may be 0.1 micrometers (μm) to 10 μm, but the disclosure is not limited thereto. In the embodiment, the roughness of the first side surface 121 of the conductive block 120 may be greater than the roughness of the second side surface 143 of the packaging layer 140 to reduce the probability of being easily separated in subsequent processes due to the difference between the coefficients of thermal expansion (CTE) of the conductive block 120 and the insulation layer 130 or the difference between the coefficients of thermal expansion of the conductive block 120 and the packaging layer 140 to improve the bonding strength between the conductive block 120 and the insulation layer 130. According to some embodiments, an organic material or a filling material in the insulation layer 130 may contact the conductive block 120, thereby improving the bonding force between different film layers, but the disclosure is not limited thereto.

In the embodiment, the roughness of the third side surface 131 of the insulation layer 130 may be greater than or equal to the roughness of the second side surface 143 of the packaging layer 140 to reduce the probability of being easily separated in subsequent processes due to the difference between the coefficients of thermal expansion of the insulation layer 130 and the packaging layer 140, so as to improve the bonding strength between the insulation layer 130 and the packaging layer 140. According to some embodiments, an organic material or a filling material in the packaging layer 140 may contact the insulation layer 130, thereby improving the bonding force between different film layers, but the disclosure is not limited thereto.

In the embodiment, the seed layers (that is, the first seed layer SL1 and the second seed layer SL2) between the first circuit structure 150 and the conductive block 120 have a thickness T1, and the seed layer (that is, the third seed layer SL3) between the second circuit structure 160 and the conductive block 120 has a thickness T2. Here, the thickness T1 is, for example, the maximum total thickness of the first seed layer SL1 and the second seed layer SL2 measured along the direction Z, and the thickness T2 is, for example, the maximum thickness of the third seed layer SL3 measured along the direction Z. In the embodiment, the thickness T1 of the seed layers between the first circuit structure 150 and the conductive block 120 may be different from the thickness T2 of the seed layer between the second circuit structure 160 and the conductive block 120. In some embodiments, the thickness T1 may be greater than the thickness T2, but the disclosure is not limited thereto.

The conductive member 170 is disposed on the second circuit structure 160 and in the opening O3 of the dielectric layer 162. The conductive member 170 may contact the conductive layer 161 of the second circuit structure 160.

Next, a manufacturing method of the packaging device 100 of the embodiment will be described below. In the embodiment, the manufacturing method of the packaging device 100 may include the following steps, wherein the order of the steps and the actual operation manner described in the embodiment may be adjusted according to requirements and are not limited to as described in the embodiment:

Please refer to FIG. 1A. The conductive block 120 and the insulation layer 130 are formed. Specifically, before the subsequent step of disposing the conductive block 120 on a carrier S2, a method of forming the conductive block 120 and the insulation layer 130 may include the following steps.

First, a carrier S1 is provided, a release layer RL1 is formed on the carrier S1, and a seed layer SL1a is formed on the release layer RL1. The carrier S1 may include a rigid substrate, a flexible substrate, or a combination thereof. For example, the material of the carrier S1 may include glass, multilayer glass, quartz, sapphire, ceramics, polycarbonate (PC), polyimide (PI), polyethylene terephthalate (PET), other suitable substrate materials, a silicon substrate, a semiconductor structure substrate, or a combination thereof, but the disclosure is not limited thereto. The material of the release layer RL1 may include a thermal release tape (HRT) or other materials that lose adhesive properties when exposed to heat or light, but the disclosure is not limited thereto.

Next, the conductive block 120 is formed by adopting photolithography, etching, developing, or other suitable process steps. For example, a photoresist or a dry film (not shown) is formed on the release layer RL1, and the photoresist is patterned to form an opening (not shown) exposing a part of the seed layer SL1a.

Next, a metal block 120a is formed on the carrier S1 and in the opening of the photoresist, wherein the metal block 120a has an upper surface 123a and a side surface 121a.

Next, the photoresist is removed, and the upper surface 123a and the side surface 121a of the metal block 120a are roughened. A method of roughening may include acid etching, alkali etching, or laser etching, but the disclosure is not limited thereto.

Next, the seed layer SLla not covered by the metal block 120a is removed to form the first seed layer SL1 covered by the metal block 120a. The side surface SL11 of the first seed layer SL1 is not flush with the side surface 121a of the metal block 120a, and a distance D1 between the side surface SL11 of the first seed layer SL1 and the side surface 121a of the metal block 120a in the direction X may be 0.05 μm to 2 μm, but the disclosure is not limited thereto. The direction X is, for example, a direction perpendicular to the direction Z, but the disclosure is not limited thereto.

Next, the insulation layer 130 is formed on the carrier S1, so that the insulation layer 130 may surround the upper surface 123a and the side surface 121a of the metal block 120a, and the insulation layer 130 may surround the side surface SL11 of the first seed layer SL1. The material of the insulation layer 130 may include photosensitive polyimide (PSPI), polybenzoxazole (PBO), ajinomoto build-up layer (ABF), epoxy, other suitable polymers, or a combination thereof, but the disclosure is not limited thereto. According to some embodiments, the insulation layer 130 may include filling particles dispersed in the aforementioned material, such as being dispersed in resin, PSPI, or other suitable polymers. The filling particles may include oxide, such as silicon oxide, aluminum oxide, titanium oxide, or other suitable materials. The particle size of the filling particles may be between 0.01 μm and 20 μm, and the average particle size may be between 1 μm and 10 μm, but the disclosure is not limited thereto.

Next, the insulation layer 130 is polished until the upper surface 123a of the metal block 120a is exposed. The upper surface 123a of the metal block 120a is flush with a surface of the insulation layer 130 away from the carrier S1. The grinding step may further include a dry etching or wet etching process.

Next, the insulation layer 130 is cut to obtain the conductive block 120 surrounded by the insulation layer 130, the insulation layer 130 is roughened such that the insulation layer 130 has the third side surface 131, and the carrier S1 and the release layer RL1 are removed as shown in FIG. 1A and FIG. 1H. The cutting step includes knife cutting, laser cutting, or other suitable steps.

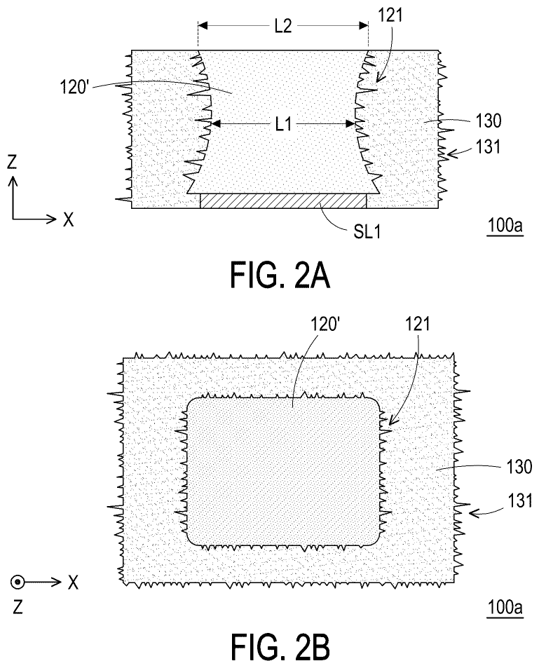

In the embodiment, as shown in the cross-sectional view of FIG. 1A, the shape of the conductive block 120 may be a column, a rectangle, or a square, and the first side surface 121 of the conductive block 120 may roughly be a straight line, but the disclosure is not limited thereto. In some embodiments, the first side surface of the conductive block may also be an arc type, as shown in FIG. 2A.

In the embodiment, as shown in the top view of FIG. 1H, the shape of the conductive block 120 may be in a column, a rectangle, or a square with a vertex, but the disclosure is not limited thereto. In some embodiments, the shape of the conductive block may also be a circle. In some embodiments, the shape of the conductive block may be a column, a rectangle, or a square with rounded corners, as shown in FIG. 2B.

At this point, the conductive block 120 and the insulation layer 130 are roughly completed.

Then, please refer to FIG. 1B. The carrier S2 is provided, a release layer RL2 is formed on the carrier S2, the conductive block 120 is disposed on the carrier S2, the electronic unit 110 is disposed on the carrier S2, and the packaging layer 140 is formed on the carrier S2, so that the packaging layer 140 may surround the electronic unit 110 and the conductive block 120. The material of the carrier S2 may be similar to that of the carrier S1, and the material of the release layer RL2 may be similar to that of the release layer RL1, so there will be no elaboration. According to some embodiments, multiple conductive blocks 120 or multiple electronic units 110 may be disposed.

Next, please continue to refer to FIG. 1B. A surface treatment step including a grinding process, an etching process, or other suitable process methods is performed to expose the back surface 1112 of the chip 111 and a flat surface 123 of the conductive block 120 through removing a part of the packaging layer 140. In the embodiment, the back surface 1112 of the chip 111 may be flush with the flat surface 123 of the conductive block 120, but the disclosure is not limited thereto.

Then, please refer to FIG. 1C to FIG. 1E. The second seed layer SL2 and the first circuit structure 150 are formed on the first surface 141 of the packaging layer 140, so that the first circuit structure 150 may be electrically connected to the conductive block 120 and the electronic unit 110 through the second seed layer SL2.

Specifically, please continue to refer to FIG. 1C. A release layer RL3 is first formed on the back surface 1112 of the chip 111, and a carrier S3 is bonded onto the release layer RL3. Then, after flipping up and down and left and right, the carrier S2 and the release layer RL2 are removed to expose the first seed layer SL1 and the pad 114 of the electronic unit 110. At this time, in the direction Z, there is a distance D2 between a surface 1131 of the second insulation layer 113 away from the chip 111 and the first surface 141 of the packaging layer 140, and there is a distance D3 between a surface 133 of the insulation layer 130 flush with the first seed layer SL1 and the first surface 141 of the packaging layer 140. The surface 133 of the insulation layer 130 and the first surface 141 of the packaging layer 140 are not flush with the conductive block 120. In the embodiment, the distance D2 and the distance D3 may be 1 μm to 10 μm to reduce the probability of the first seed layer SL1 being separated from the second insulation layer 113 or the insulation layer 130, but the disclosure is not limited thereto. In the embodiment, the material of the carrier S3 may be similar to that of the carrier S1, and the material of the release layer RL3 may be similar to that of the release layer RL1, so there will be no elaboration.

Next, please continue to refer to FIG. 1C. The second seed layer SL2 is formed on the insulation layer 130, on the first seed layer SL1, on the first surface 141 of the packaging layer 140, and in the opening O2 of the second insulation layer 113, and the conductive layer 151 is formed on the second seed layer SL2 and in the opening O2 of the second insulation layer 113. According to some embodiments, before forming the second seed layer SL2, a cleaning step may be included. For example, a surface treatment step may be included to reduce the influence of contact impedance through cleaning contaminants in the opening O2 of the second insulation layer 113, but the disclosure is not limited thereto. The surface treatment step includes laser, etching, plasma, or other suitable methods.

Next, please refer to FIG. 1D. The conductive layer 151 is roughened, so that the conductive layer 151 has a rough surface 1511.

Next, please refer to FIG. 1E. The dielectric layer 152 is formed on the conductive layer 151. The material of the dielectric layer 152 may be similar to that of the insulation layer 130, so there will be no elaboration. In the embodiment, since the conductive layer 151 has the rough surface 1511, the probability of being easily separated in subsequent processes due to the difference between the coefficients of thermal expansion of the conductive layer 151 and the dielectric layer 152 may be reduced or the bonding strength between the conductive layer 151 and the dielectric layer 152 may be improved. At this point, the first circuit structure 150 is roughly completed.

Then, please refer to FIG. 1F to FIG. 1G. The second circuit structure 160 is formed, so that the second circuit structure 160 is disposed opposite to the first circuit structure 150, and the second circuit structure 160 may be electrically connected to the first circuit structure 150 through the conductive block 120.

Specifically, please continue to refer to FIG. 1F. A release layer RL4 is first formed on the first circuit structure 150, and a carrier S4 is bonded onto the release layer RL4. Then, after flipping up and down and left and right, the carrier S3 and the release layer RL3 are removed to expose the back surface 1112 of the chip 111 and the flat surface 123 of the conductive block 120 facing away from the first circuit structure 150. The material of the carrier S4 may be similar to that of the carrier S1, and the material of the release layer RL4 may be similar to that of the release layer RL1, so there will be no elaboration.

Next, please continue to refer to FIG. 1F, the third seed layer SL3 is formed on the insulation layer 130, the flat surface 123 of the conductive block 120 facing away from the first circuit structure 150, the back surface 1112 of the chip 111, and the second surface 142 of the packaging layer 140, the conductive layer 161 is formed on the third seed layer SL3, and the conductive layer 161 is roughened such that the conductive layer 161 has a rough surface 1611.

Next, please continue to refer to FIG. 1F. The dielectric layer 162 is formed on the conductive layer 161, and a grinding process is performed to remove a part of the dielectric layer 162 to expose a flat surface 1612 of the conductive layer 161 facing away from the first circuit structure 150. The material of the dielectric layer 162 may be similar to that of the insulation layer 130, so there will be no elaboration. In the embodiment, since the conductive layer 161 has the rough surface 1611, the probability of being easily separated in subsequent processes due to the difference between the coefficients of thermal expansion of the conductive layer 161 and the dielectric layer 162 may be reduced or the bonding strength between the conductive layer 161 and the dielectric layer 162 may be improved.

Next, please refer to FIG. 1F. The partially exposed conductive layer 161 is etched to form an opening O3 of the dielectric layer 162, and a conductive member 170 is formed in the opening O3 of the dielectric layer 162. In the embodiment, the opening O3 has a depth D4 in the direction Z, and the depth D4 may be 5 μm to 30 μm, but the disclosure is not limited thereto. The depth D4 is, for example, a distance measured along the direction Z between a surface 1621 of the dielectric layer 162 away from the packaging layer 140 and the flat surface 1612 of the conductive layer 161 away from the packaging layer 140. In the embodiment, the conductive member 170 may be used to be bonded to a circuit board (not shown) or other electronic devices, and the material of the conductive member 170 may include tin, nickel, gold, palladium, other suitable metals, or a combination thereof, but the disclosure is not limited thereto. In the embodiment, when the packaging device 100 is bonded to the circuit board or contacts other electronic devices through the conductive member 170, since the conductive member 170 is disposed in the opening O3 of the dielectric layer 162, the bonding strength between the packaging device 100 and the circuit board (or other electronic devices) may be improved. At this point, the second circuit structure 160 is roughly completed.

Then, please refer to FIG. 1G. The carrier S4 and the release layer RLA are removed. At this point, the packaging device 100 of the embodiment is roughly completed.

In some embodiments, the packaging device 100 includes the conductive block 120, which may, for example, reduce issues such as difficulty in drilling or poor electroplating effect due to the thickness of the packaging layer being too thick, thereby improving yield.

In the manufacturing method of the packaging device 100 of the embodiment, although a chip first/face down manufacturing method is used as an example, that is, the electronic unit 110 containing the chip 111 is first disposed on the carrier S2 with the active surface 1111 facing the carrier S2, the electronic unit 110 is then surrounded by the packaging layer 140, and the first circuit structure 150 and the second circuit structure 160 are then formed on the packaging layer 140, the disclosure does not limit the orientation of the active surface 1111 of the chip 111. In some embodiments, the manufacturing method of the packaging device 100 may also be a chip first/face up manufacturing method, that is, the electronic unit containing the chip is first disposed on the carrier with the active surface facing away from the carrier, and the electronic unit is then surrounded by the packaging layer, and the first circuit structure and the second circuit structure are then formed on the packaging layer.

Other embodiments are listed below for illustration. It must be noted here that the following embodiments continue to use the reference numerals and some content of the foregoing embodiment, wherein the same numerals are adopted to represent the same or similar elements, and the description of the same technical content is omitted. Reference may be made to the foregoing embodiment for the description of the omitted part, which will not be elaborated in the following embodiments.

FIG. 2A is a cross-sectional schematic view of a conductive block of a packaging device according to a second embodiment of the disclosure. FIG. 2B is a top schematic view of a conductive block of FIG. 2A. Please refer to FIG. 2A, FIG. 2B, FIG. 1A, and FIG. 1H at the same time. A conductive block 120′ of the embodiment is similar to the conductive block 120 of FIG. 1A and FIG. 1H, but the difference between the two is that in a packaging device 100a of the embodiment, a first side surface 121 of the conductive block 120′ may be an arc type, and the shape of the conductive block 120′ may be a column, a rectangle, or a square with rounded corners. The arc type referred to in the disclosure represents that the conductive block 120 may have different widths. For example, the width of the conductive block 120 gradually changes along the direction Z, so that the conductive block 120 may have a minimum width L1 and a maximum width L2. The conductive block 120 may also be applied to other embodiments of the disclosure.

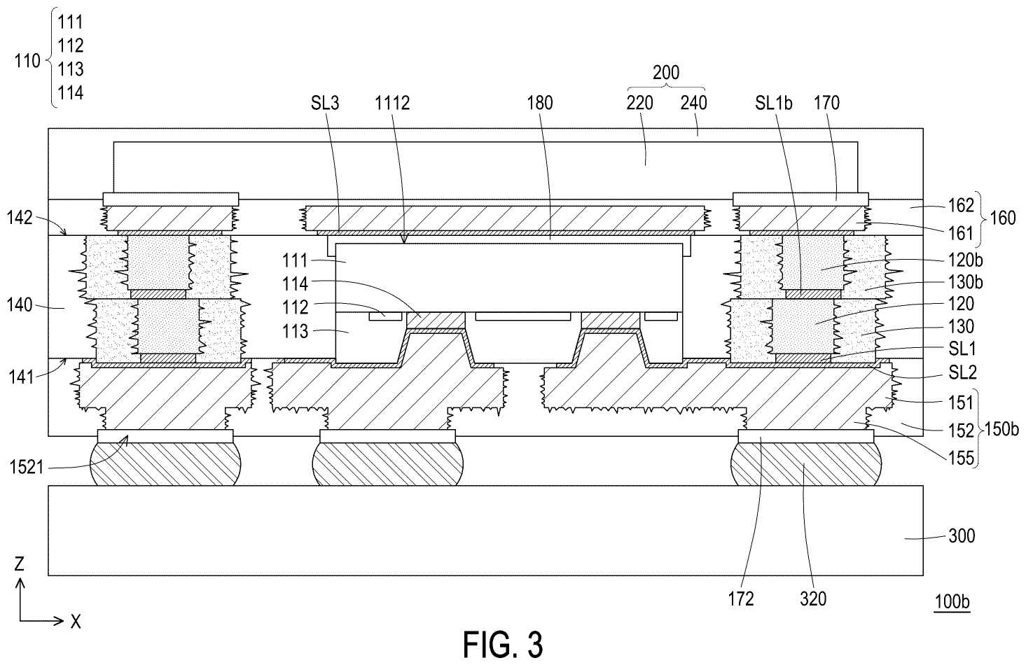

FIG. 3 is a cross-sectional schematic view of a packaging device according to a third embodiment of the disclosure. Please refer to FIG. 3 and FIG. 1G at the same time. A packaging device 100b of the embodiment is another variation of the packaging device 100 of FIG. 1G. For example, the packaging device 100b is formed by stacking multiple packaging units along the direction Z, and the difference between the two is that the packaging device 100b of the embodiment further includes a conductive block 120b, a first seed layer SL1b, an insulation layer 130b, a conductive member 172, a heat dissipation adhesive 180, a packaging unit 200, a printed circuit board 300, and a solder ball 320.

Specifically, please refer to FIG. 3. The conductive block 120b is disposed on the conductive block 120, and the conductive block 120b and the conductive block 120 are stacked along the direction Z. The conductive block 120b may be electrically connected to the conductive block 120.

The first seed layer SL1b is disposed between the conductive block 120b and the conductive block 120. The first seed layer SL1b may overlap with the conductive block 120b, and the first seed layer SL1b may contact the conductive block 120b.

The insulation layer 130b may surround and contact the conductive block 120b and the first seed layer SL1b.

The first circuit structure 150b may be electrically connected to the second circuit structure 160b through the first seed layer SL1, the conductive block 120, the first seed layer SL1b, and the conductive block 120b. The first circuit structure 150b further includes a via 155 penetrating the dielectric layer 152, and the via 155 may be electrically connected to the conductive layer 151. The dielectric layer 152 in the first circuit structure 150b has an opening 1521 that may expose the via 155.

The conductive member 172 is disposed in the opening 1521 of the dielectric layer 152 and contacts the via 155.

The printed circuit board 300 is disposed on a side of the first circuit structure 150b facing away from the chip 111. The solder ball 320 is disposed between the conductive member 172 and the printed circuit board 300. The printed circuit board 300 may be electrically connected to the first circuit structure 150b through the solder ball 320 and the conductive member 172.

The packaging unit 200 is disposed on a side of the second circuit structure 160 facing away from the chip 111. The packaging unit 200 at least includes an electronic unit 220 and a packaging layer 240. The electronic unit 220 may be electrically connected to the second circuit structure 160 through the conductive member 170. The packaging layer 240 may surround the electronic unit 220.

The chip 111 may be electrically connected to the electronic unit 220 in the packaging unit 200 through the first circuit structure 150b, the conductive block 120, the conductive block 120b, the second circuit structure 160, and the conductive member 170. The chip 111 may also be electrically connected to the printed circuit board 300 through the first circuit structure 150b, the conductive member 172, and the solder ball 320.

The heat dissipation adhesive 180 is disposed between the back surface 1112 of the chip 111 of the electronic unit 110 and the third seed layer SL3 of the second circuit structure 160, so that heat generated by the chip 111 may be conducted from the back surface 1112 of the chip 111 to the outside through the heat dissipation adhesive 180.

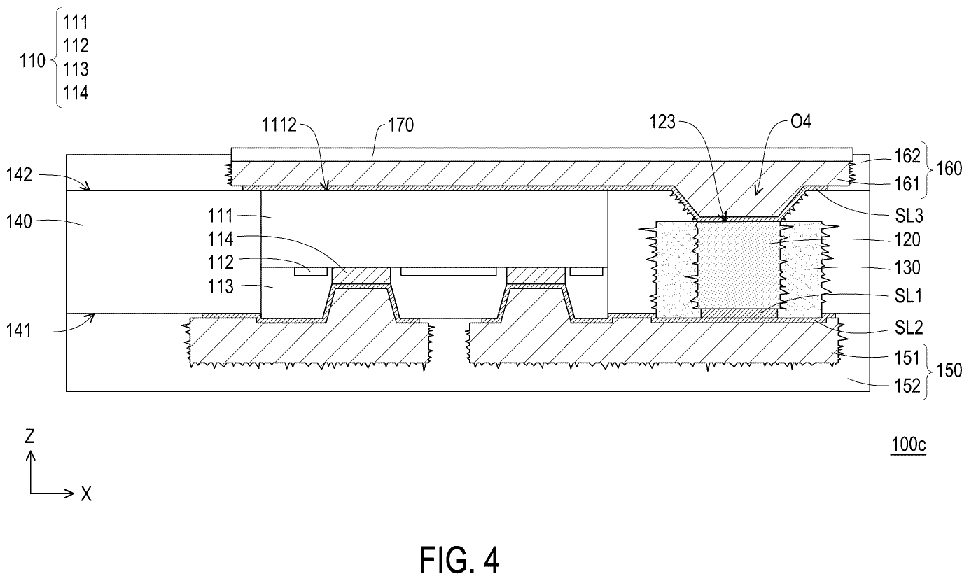

FIG. 4 is a cross-sectional schematic view of a packaging device according to a fourth embodiment of the disclosure. Please refer to FIG. 4 and FIG. 1G at the same time. A packaging device 100c of the embodiment is similar to the packaging device 100 of FIG. 1G, but the difference between the two is that in the packaging device 100c of the embodiment, the back surface 1112 of the chip 111 is higher than the flat surface 123 of the conductive block 120 in the direction Z.

Specifically, please refer to FIG. 4. The packaging layer 140 includes an opening O4, and the opening O4 may expose the flat surface 123 of the conductive block 120.

The third seed layer SL3 is disposed on the second surface 142 of the packaging layer 140, on the back surface 1112 of the chip 111, and in the opening O4 of the packaging layer 140, and the third seed layer SL3 may contact the conductive block 120.

The conductive layer 161 of the second circuit structure 160 is disposed on the third seed layer SL3 and in the opening O4 of the packaging layer 140. The second circuit structure 160 is electrically connected to the conductive block 120 through the opening O4.

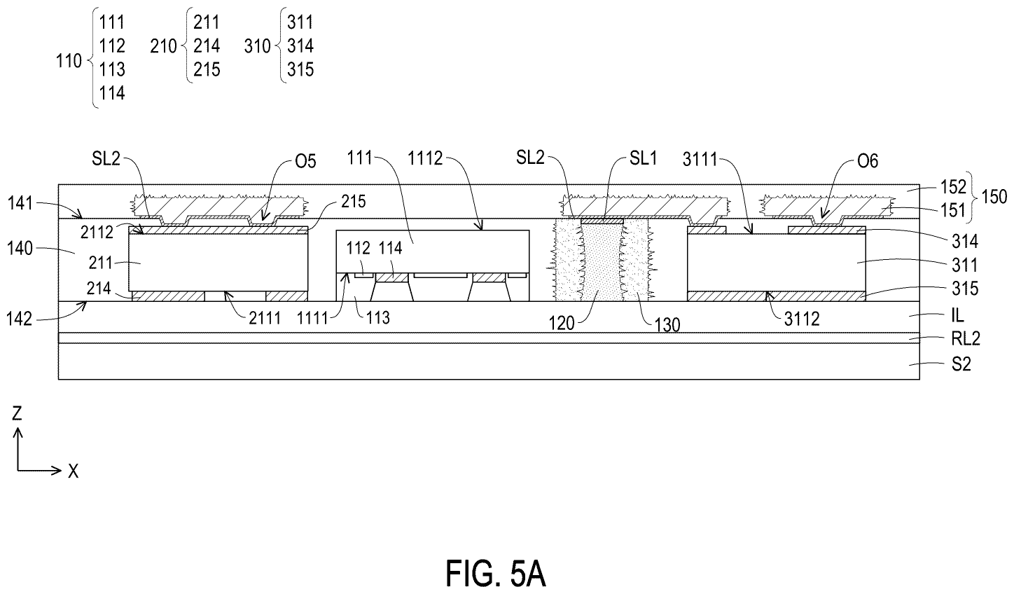

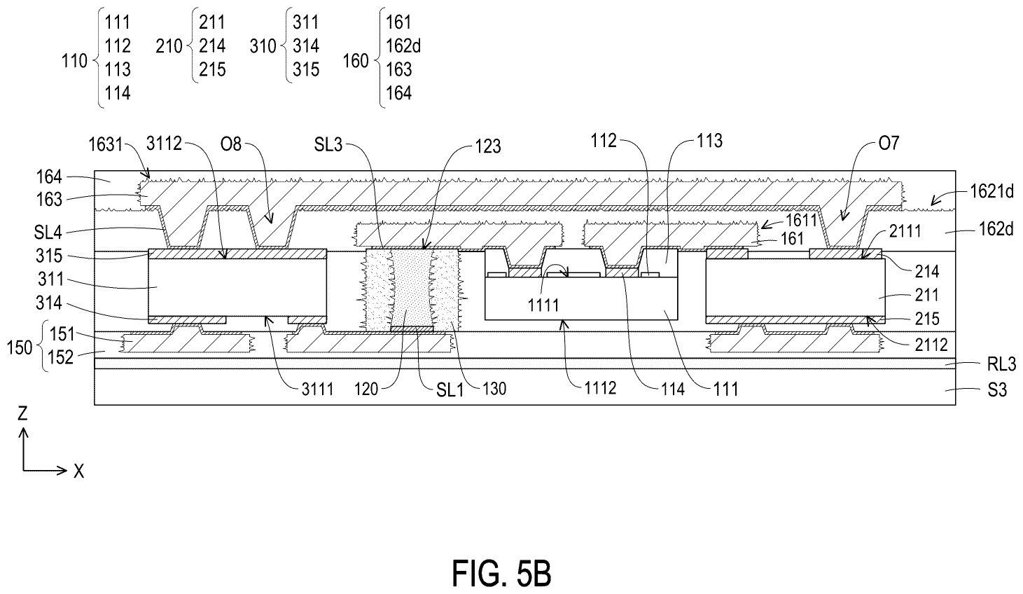

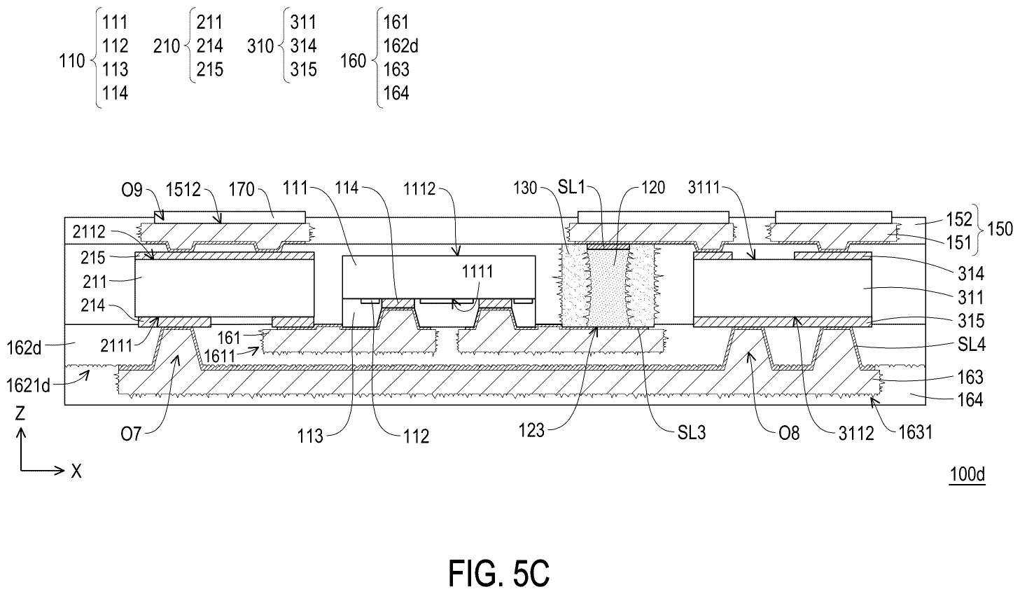

FIG. 5A to FIG. 5C are cross-sectional schematic views of a manufacturing method of a packaging device according to a fifth embodiment of the disclosure. FIG. 5A to FIG. 5C are steps subsequent to FIG. 1A and replacing the steps of FIG. 1B to FIG. 1G. The same or similar components in the embodiment of FIG. 5A to 5C and the embodiment of FIG. 1A to 1G may adopt the same materials or methods, so the same or similar description in the two embodiments will not be elaborated, and the difference between the two embodiments will be mainly described.

Specifically, a manufacturing method of a packaging device 100d of the embodiment may include the following steps.

Please refer to FIG. 5A. The carrier S2 is provided, the release layer RL2 is formed on the carrier S2, an insulation layer IL is formed on the release layer RL2, the electronic unit 110, the conductive block 120 of FIG. 1A, an electronic unit 210, and an electronic unit 310 are respectively disposed on the carrier S2, and the packaging layer 140 is formed on the carrier S2 so that the packaging layer 140 may surround the electronic unit 110, the conductive block 120, the electronic unit 210, and the electronic unit 310. The active surface 1111 of the chip 111 in the electronic unit 110 faces the carrier S2.

In the embodiment, the electronic unit 210 includes a chip 211, a pad 214, and a pad 215. The chip 211 has an active surface 2111 and a back surface 2112 opposite to each other, and the active surface 2111 faces the carrier S2. The pad 214 is disposed under the active surface 2111 of the chip 211, and the pad 215 is disposed on the back surface 2112 of the chip 211.

In the embodiment, the electronic unit 310 includes a chip 311, a pad 314, and a pad 315. The chip 311 has an active surface 3111 and a back surface 3112 opposite to each other, and the active surface 3111 faces away from the carrier S2. The pad 314 is disposed on the active surface 3111 of the chip 311, and the pad 315 is disposed under the back surface 3112 of the chip 311.

Next, a grinding process is performed to remove a part of the packaging layer 140 and expose the first seed layer SL1 and the insulation layer 130.

Next, an etching process is performed to form an opening O5 and an opening O6 of the packaging layer 140. The opening O5 may expose the pad 215 of the electronic unit 210, and the opening O6 may expose the pad 314 of the electronic unit 310.

Next, the second seed layer SL2 and the first circuit structure 150 are formed on the first surface 141 of the packaging layer 140, so that the electronic unit 310 may be electrically connected to the conductive block 120 through the second seed layer SL2, the first circuit structure 150, and the first seed layer SL1.

Then, please refer to FIG. 5B. The release layer RL3 is formed on the first circuit structure 150, and the carrier S3 is bonded to the release layer RL3. Next, after flipping up and down and left and right, the carrier S2 and the release layer RL2 are removed, and the insulation layer IL is removed by grinding to expose the pad 114 of the electronic unit 110, the pad 214 of the electronic unit 210, the pad 315 of the electronic unit 310, and the flat surface 123 of the conductive block 120 facing away from the first circuit structure 150.

Next, the third seed layer SL3 is formed on the insulation layer 130, the flat surface 123 of the conductive block 120, the pad 114 of the electronic unit 110, and the pad 214 of the electronic unit 210, the conductive layer 161 is formed on the third seed layer SL3, and the conductive layer 161 is roughened such that the conductive layer 161 has the rough surface 1611.

Next, a dielectric layer 162d is formed on the conductive layer 161, the dielectric layer 162d is roughened to form a rough surface 1621d, and an etching process is performed to form an opening O7 and an opening O8 of the dielectric layer 162d. The opening O7 may expose another pad 214 of the electronic unit 210, and the opening O8 may expose the pad 315 of the electronic unit 310.

Next, a fourth seed layer SL4 is formed on the dielectric layer 162d, in the opening O7, and in the opening O8, a conductive layer 163 is formed on the fourth seed layer SL4, and the conductive layer 163 is roughened such that the conductive layer 163 has a rough surface 1631.

Next, a dielectric layer 164 is formed on the conductive layer 163. At this point, the second circuit structure 160d is roughly completed. The second circuit structure 160d includes the conductive layer 161, the dielectric layer 162d, the conductive layer 163, and the dielectric layer 164.

In the embodiment, since the dielectric layer 162d has the rough surface 1621d, the probability of separation between the dielectric layer 162d and the dielectric layer 164 may be reduced or the bonding strength between the dielectric layer 162d and the dielectric layer 164 may be increased.

In the embodiment, electronic unit 110 may be electrically connected to electronic unit 210 through the conductive layer 161 of the second circuit structure 160d, the electronic unit 210 may be electrically connected to the electronic unit 310 through the conductive layer 163 of the second circuit structure 160d, and the electronic unit 310 may be electrically connected to the electronic unit 310 through the conductive layer 151 of the first circuit structure 150.

Then, please refer to FIG. 5C. The carrier S3 and the release layer RL3 are removed, and a grinding process is performed to remove a part of the dielectric layer 152 and expose a flat surface 1512 of the conductive layer 151.

Next, the partially exposed conductive layer 151 is etched to form an opening O9 of the dielectric layer 152, and the conductive member 170 is formed in the opening O9 of the dielectric layer 152. At this point, the packaging device 100d of the embodiment is roughly completed.

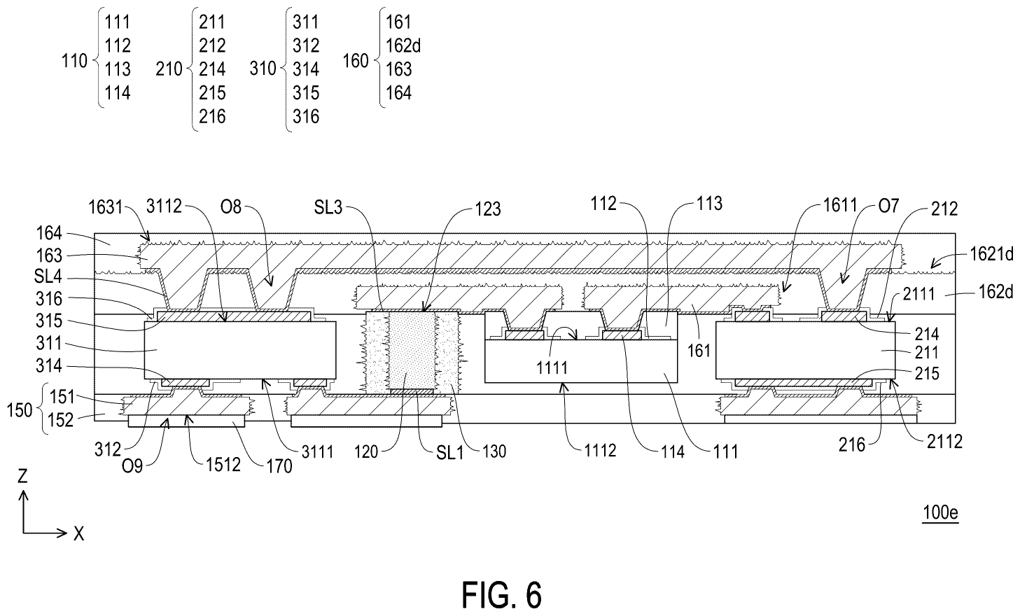

FIG. 6 is a cross-sectional schematic view of a packaging device according to a sixth embodiment of the disclosure. Please refer to FIG. 6 and FIG. 5C at the same time. A packaging device 100e of the embodiment is similar to the packaging device 100d of FIG. 5C, but the difference between the two is that in the packaging device 100e of the embodiment, the electronic unit 210 further includes a first insulation layer 212 and a first insulation layer 216, and the electronic unit 310 further includes a first insulation layer 312 and a first insulation layer 316.

Specifically, please refer to FIG. 6. The first insulation layer 112 of the electronic unit 110 is disposed on the active surface 1111 of the chip 111. The first insulation layer 112 may cover the pad 114, and the second insulation layer 113 may cover the first insulation layer 112.

In the embodiment, the first insulation layer 212 of the electronic unit 210 is disposed under the active surface 2111 of the chip 211, and the first insulation layer 212 may cover the pad 214. The first insulation layer 216 is disposed on the back surface 2112 of the chip 211, and the first insulation layer 216 may cover the pad 215.

In the embodiment, the first insulation layer 312 of the electronic unit 310 is disposed on the active surface 3111 of the chip 311, and the first insulation layer 312 may cover the pad 314. The first insulation layer 316 is disposed under the back surface 3112 of the chip 311, and the first insulation layer 316 may cover the pad 315.

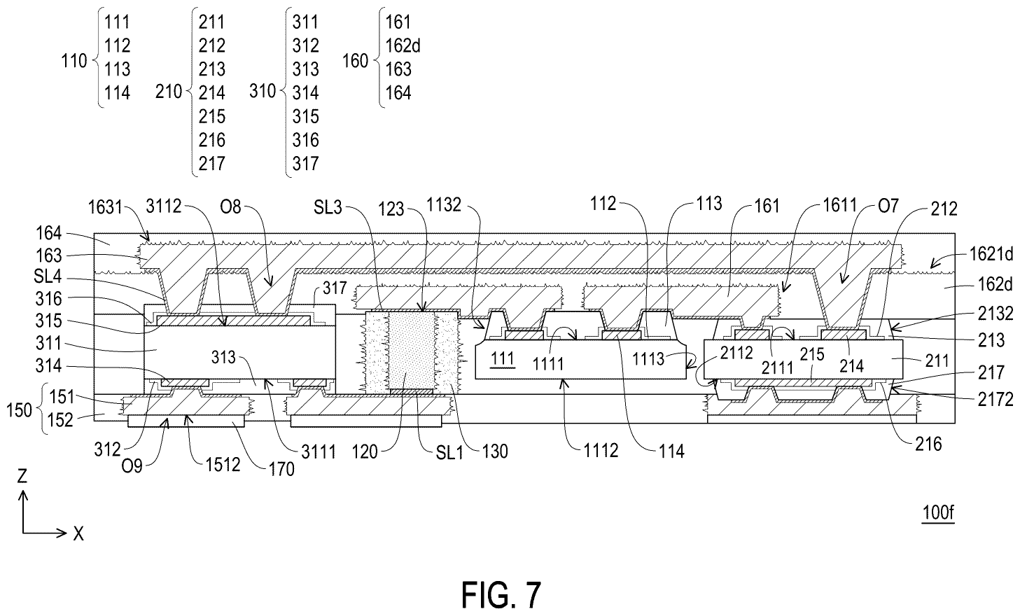

FIG. 7 is a cross-sectional schematic view of a packaging device according to a seventh embodiment of the disclosure. Please refer to FIG. 7 and FIG. 6 at the same time. A packaging device 100f of the embodiment is similar to the packaging device 100e of FIG. 6, but the difference between the two is that in the packaging device 100f of the embodiment, the electronic unit 210 further includes a second insulation layer 213 and a second insulation layer 217, and the electronic unit 310 further includes a second insulation layer 313 and a second insulation layer 317.

Specifically, please refer to FIG. 7. A side surface 1132 of the second insulation layer 113 of the electronic unit 110 is an inclined surface to improve the bonding strength between the second insulation layer 113 and the packaging layer 140 through increasing the contact area between the two.

There is an arced surface at a junction between the active surface 1111 and the side surface 1113 of the chip 111 of the electronic unit 110 to improve the bonding strength between the chip 111 and the packaging layer 140 through increasing the contact area between the two.

In the embodiment, the second insulation layer 213 of the electronic unit 210 is disposed under the active surface 2111 of the chip 211, and the second insulation layer 213 may cover the first insulation layer 212. The second insulation layer 217 is disposed on the back surface 2112 of the chip 211, and the second insulation layer 217 may cover the first insulation layer 216. Since a side surface 2132 of the second insulation layer 213 (or a side surface 2172 of the second insulation layer 217) is an inclined surface, the bonding strength between the second insulation layer 213 (or the second insulation layer 217) and the packaging layer 140 may be improved through increasing the contact area between the two.

In the embodiment, the second insulation layer 313 of the electronic unit 310 is disposed on the active surface 3111 of the chip 311, and the second insulation layer 313 may cover the first insulation layer 312. The second insulation layer 317 is disposed under the back surface 3112 of the chip 311, and the second insulation layer 317 may cover the first insulation layer 316.

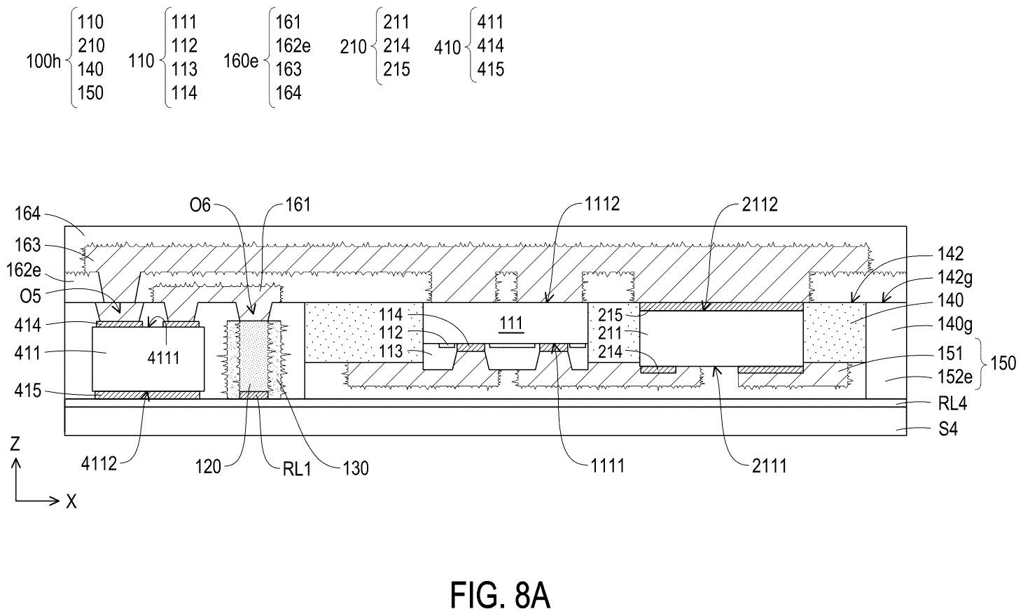

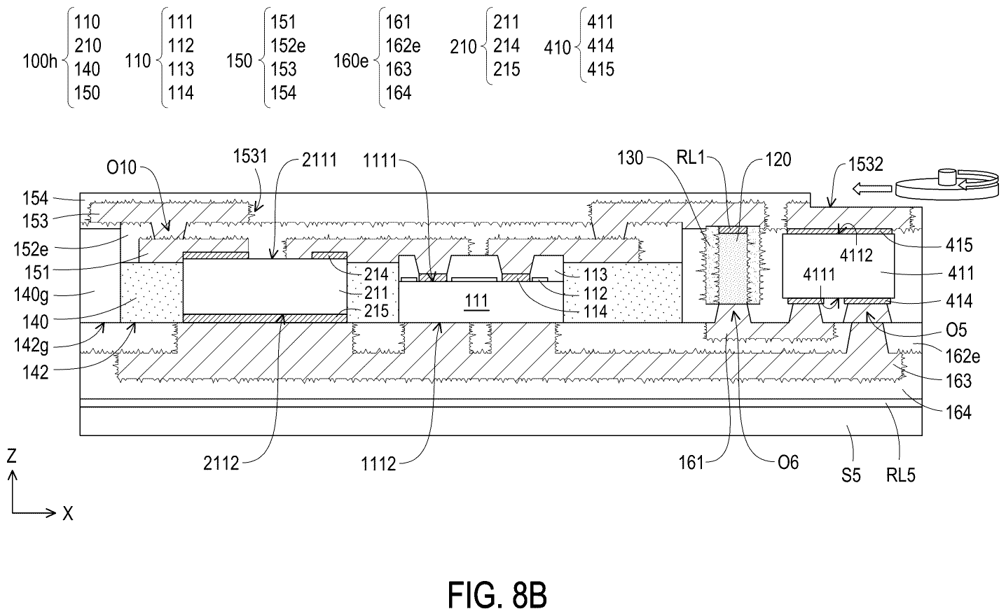

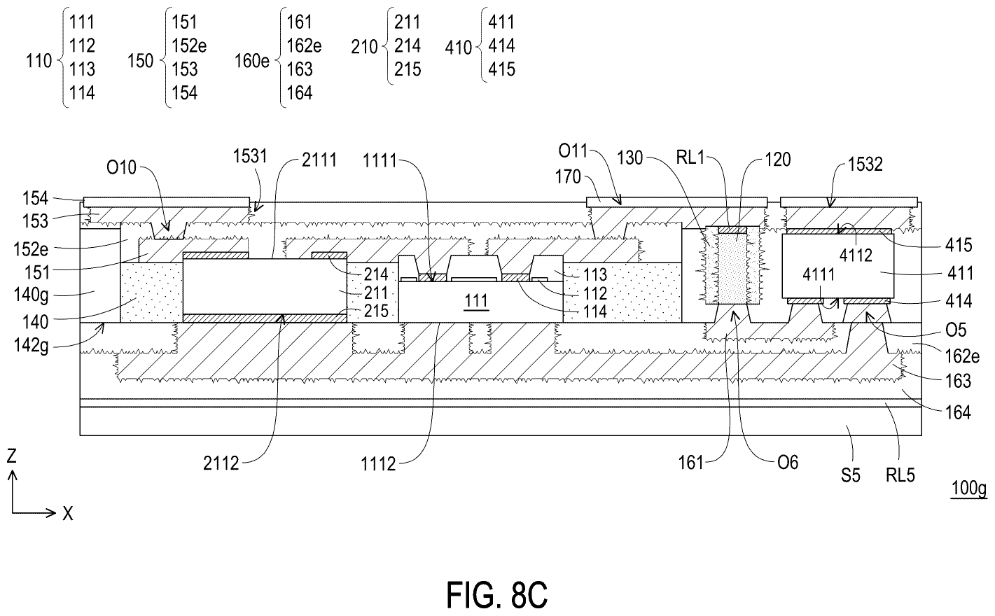

FIG. 8A to FIG. 8C are cross-sectional views of a manufacturing method of a packaging device according to an eighth embodiment of the disclosure. FIG. 8A to FIG. 8C are steps subsequent to FIG. 1A and replacing the steps of FIG. 1B to FIG. 1E. The same or similar components in the embodiment of FIG. 8A to FIG. 8C and the embodiment of FIG. 1A to FIG. 1E adopt the same materials or methods, so the same or similar description in the two embodiments will not be elaborated, and the difference between the two embodiments will be mainly described. For the sake of clarity of the drawings and convenience of explanation, several elements (for example, seed layers) in a packaging device 100g are omitted in FIG. 8A to FIG. 8C.

Specifically, a manufacturing method of the packaging device 100g of the embodiment may include the following steps.

Please refer to FIG. 8A. A carrier S4 is provided, a release layer RL4 is formed on the carrier S4, a packaging device 100h, the conductive block 120 of FIG. 1A, and an electronic unit 410 are respectively disposed on the carrier S4, and a packaging layer 140g is formed on the carrier S4, so that the packaging layer 140g may surround the packaging device 100h, the conductive block 120, and the electronic unit 410.

In the embodiment, the packaging device 100h includes the electronic unit 110, the electronic unit 210, the packaging layer 140, and the first circuit structure 150. The packaging layer 140 may surround the electronic unit 110 and the electronic unit 210. The electronic unit 110 may be electrically connected to the electronic unit 210 through the first circuit structure 150. The active surface 1111 of the chip 111 in the electronic unit 110 faces the carrier S4.

In the embodiment, the electronic unit 210 includes the chip 211, the pad 214, and the pad 215. The chip 211 has the active surface 2111 and the back surface 2112 opposite to each other, and the active surface 2111 faces the carrier S4. The pad 214 is disposed under the active surface 2111 of the chip 211, and the pad 215 is disposed on the back surface 2112 of the chip 211.

In the embodiment, the electronic unit 410 includes a chip 411, a pad 414, and a pad 415. The chip 411 has an active surface 4111 and a back surface 4112 opposite to each other, and the active surface 4111 faces away from the carrier S4. The pad 414 is disposed on the active surface 4111 of the chip 411, and the pad 415 is disposed under the back surface 4112 of the chip 411.

Next, a grinding process is performed to remove a part of the packaging layer 140g and expose the back surface 1112 of the chip 111 of the electronic unit 110 and the pad 215 of the electronic unit 210.

Next, an etching process is performed to form the opening O5 and the opening O6 of the packaging layer 140g. The opening O5 may expose the pad 414 of the electronic unit 410, and the opening O6 may expose the conductive block 120.

Next, a second circuit structure 160e is formed on a second surface 142g of the packaging layer 140g and the second surface 142 of the packaging layer 140. The second circuit structure 160e includes the conductive layer 161, a dielectric layer 162e, the conductive layer 163, and the dielectric layer 164. The electronic unit 410 may be electrically connected to the conductive block 120 through the conductive layer 161 of the second circuit structure 160e. The electronic unit 410 may be electrically connected to the electronic unit 110 and the electronic unit 210 in the packaging device 100h through the second circuit structure 160e.

Then, please refer to FIG. 8B. A release layer RL5 is first formed on the second circuit structure 160e, and a carrier S5 is bonded to the release layer RL5. Next, after flipping up and down and left and right, the carrier S4 and the release layer RL4 are removed to expose the first circuit structure 150, the first seed layer SL1, and the pad 414 of the electronic unit 410. The material of the carrier S5 may be similar to that of the carrier S1, and the material of the release layer RL5 may be similar to that of the release layer RL1, so there will be no elaboration.

Next, an etching process is performed to form an opening O10 of a dielectric layer 152e. The opening O10 may expose the conductive layer 151 of the first circuit structure 150.

Next, a conductive layer 153 is formed on the dielectric layer 152e and in the opening O10, and the conductive layer 153 is roughened, so that the conductive layer 153 has a rough surface 1531.

Next, a dielectric layer 154 is formed on the conductive layer 153, and a grinding process is performed to remove a part of the dielectric layer 154 and expose a flat surface 1532 of the conductive layer 153.

Then, please refer to FIG. 5C. The partially exposed conductive layer 153 is etched to form an opening O11 of the dielectric layer 154, and the conductive member 170 is formed in the opening O11 of the dielectric layer 154. At this point, the packaging device 100e of the embodiment is roughly completed.

In summary, in the packaging device and the manufacturing method thereof according to the embodiments of the disclosure, the conductive block is disposed to replace the via in the conventional packaging device, thereby reducing issues such as difficulty in drilling or poor electroplating effect due to the thickness of the packaging layer being too thick, thereby improving yield. Since the roughness of the first side surface of the conductive block may be greater than the roughness of the side surface of the packaging layer, the probability of being easily separated in subsequent processes due to the difference between the coefficients of thermal expansion of the conductive block and the insulation layer may be reduced or the bonding strength between the conductive block and the insulation layer may be improved.

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. A packaging device, comprising:
an electronic unit;
a conductive block, electrically connected to the electronic unit and having a first side surface; and
a packaging layer, surrounding the electronic unit and the conductive block,
wherein a roughness of the first side surface is greater than a roughness of the second side surface of the packaging layer.

2. The package device according to claim 1, wherein the conductive block and the electronic unit are disposed along a direction perpendicular to a normal direction of the package device.

3. The packaging device according to claim 1, further comprising:
a first seed layer, overlapping with and contacting the conductive block.

4. The packaging device according to claim 1, wherein a width of the first seed layer is less than or equal to a width of the conductive block.

5. The packaging device according to claim 1, further comprising:
an insulation layer, disposed between the conductive block and the packaging layer, surrounding the conductive block, and having a third side surface,
wherein a roughness of the third side surface is greater than the roughness of the second side surface of the packaging layer.

6. The packaging device according to claim 5, wherein a part of the conductive block extends into the insulation layer.

7. The packaging device according to claim 5, wherein a part of the insulation layer extends into the packaging layer.

8. The packaging device according to claim 5, wherein a surface of the insulation layer and a first surface of the packaging layer are not flush with the conductive block, and there is a distance between the surface of the insulation layer and the first surface of the packaging layer.

9. The packaging device according to claim 1, further comprising:
a first circuit structure, disposed on the packaging layer; and
a second circuit structure, disposed opposite to the first circuit structure,
wherein the first circuit structure is electrically connected to the second circuit structure through the conductive block.

10. The packaging device according to claim 9, wherein the first circuit structure comprises at least one seed layer, at least one conductive layer, and at least one dielectric layer, wherein at least part of the at least one seed layer is disposed between the packaging layer and the at least one conductive layer, and at least part of the at least one dielectric layer is disposed between the packaging layer and the at least one conductive layer.

11. The package device according to claim 10, wherein the electronic unit is electrically connected to the conductive block through the first circuit structure.

12. The packaging device according to claim 10, wherein the at least one conductive layer has a rough surface.

13. The package device according to claim 9, wherein the package layer comprises an opening, the opening exposes the conductive block, and the second circuit structure is electrically connected to the conductive block through the opening.

14. The packaging device according to claim 9, further comprising:
a heat dissipation adhesive, disposed between the electronic unit and the second circuit structure.

15. The packaging device according to claim 1, further comprising:
another conductive block, disposed on the conductive block, overlapping with the conductive block, and electrically connected to the conductive block.

16. A manufacturing method of a packaging device, comprising:
providing a carrier;
disposing a conductive block on the carrier, wherein the conductive block has a first side surface;
disposing an electronic unit on the carrier;
forming a packaging layer on the carrier, so that the packaging layer surrounds the electronic unit and the conductive block; and
removing the carrier,
wherein a roughness of the first side surface is greater than a roughness of the second side surface of the packaging layer.

17. The manufacturing method according to claim 16, wherein before disposing the conductive block on the carrier, a method of forming the conductive block comprises:
providing another carrier;
forming a metal block on the another carrier, wherein the metal block has an upper surface and a side surface;
roughening the upper surface and the side surface of the metal block;
forming an insulation layer on the another carrier, so that the insulation layer surrounds the metal block; and
grinding the insulation layer to expose the upper surface of the metal block.

18. The manufacturing method according to claim 17, wherein the upper surface of the metal block is flush with a surface of the insulation layer away from the another carrier.

19. The manufacturing method according to claim 17, further comprising:
cutting the insulation layer to form the conductive block surrounded by the insulation layer, wherein the insulation layer has a third side surface;
roughening the insulation layer; and
removing the another carrier,
wherein a roughness of the third side surface is greater than the roughness of the second side surface of the packaging layer.

20. The manufacturing method according to claim 16, further comprising:
forming a first circuit structure on the packaging layer to electrically connect the conductive block and the electronic unit; and
forming a second circuit structure, so that the second circuit structure is disposed opposite to the first circuit structure,
wherein the first circuit structure is electrically connected to the second circuit structure through the conductive block.
